(19) United States
(12) Patent Application Publication
(10) Pub. No.: US 2026/0020358 A1
(43) Pub. Date: Jan. 15, 2026

(54) WAVEGUIDE PHOTODETECTOR INTEGRATED WITH ANTENNA, SYSTEM, AND METHOD FOR SENDING SIGNALS

(71) Applicant: Silith Technology (Suzhou) Co., Ltd., Shanghai (CN)

(72) Inventors: Xingyu ZHANG, Shanghai (CN); Ke ZHANG, Shanghai (CN)

(73) Assignee: Silith Technology (Suzhou) Co., Ltd., Shanghai (CN)

(21) Appl. No.: 18/994,145

(22) PCT Filed: Oct. 28, 2022
(86) PCT No.: PCT/CN2022/128183

§ 371 Date: Jan. 14, 2025

(30) Foreign Application Priority Data
Aug. 4, 2022 (CN) 202210935803.0

(51) Int. Cl. H10F 39/10; H01L 23/66; H01Q 1/22; H04B 10/2575; H10F 77/40

(52) U.S. Cl. CPC H10F 39/103; H01L 23/66; H01Q 1/2283; H04B 10/2575; H10F 77/413

(57) ABSTRACT

The present invention provides a waveguide photodetector integrated with an antenna, a system, and a method for sending a signal. The waveguide photodetector integrated with an antenna includes: a photodetector, N optical waveguides and an antenna, where N is a positive integer; the antenna is disposed on a substrate, and a feed gap is formed on a central axis of two arms of the antenna, the photodetector being disposed in the feed gap; and the N optical waveguides are formed on the substrate, and the photodetector is connected to the optical waveguides to obtain modulated optical signals transmitted from the optical waveguides. According to the present invention, the feed gap is formed on a central axis of two arms of the antenna, and the photodetector is disposed in the feed gap, such that the antenna and the photodetector can be integrated on a same device of a same chip, thereby improving the integration level of an optical integrated circuit and system.

### TECHNICAL FIELD

The present invention relates to the technical field of optical integrated circuits, in particular to a waveguide photodetector integrated with an antenna, a system, and a method for sending signals.

### BACKGROUND ART

The waveguide photodetector is a device commonly used in optical integrated circuits to convert optical signals into electrical signals. In some microwave photonics applications, the waveguide photodetector absorbs the incoming optical signals and converts them into electrical signals, which need to be immediately radiated into free space.

A conventional method involves adding an emitting antenna outside a photodetector chip and encapsulating them into a system. However, this method has a low integration level, complex encapsulation, and high cost.

Therefore, the present invention proposes the waveguide photodetector integrated with an antenna, the system, and the method for sending signals, to improve the integration level of a microwave photonic system.

### SUMMARY OF THE INVENTION

The present invention proposes the waveguide photodetector integrated with an antenna, the system, and the method for sending signals, for improving the integration level of a microwave photonic system.

In a first aspect, the present invention provides a waveguide photodetector integrated with an antenna, including: a photodetector, N optical waveguides and an antenna, where N is a positive integer; the antenna is disposed on a substrate, and a feed gap is formed on a central axis of two arms of the antenna, the photodetector being disposed in the feed gap; and the N optical waveguides are formed on the substrate, and the photodetector is connected to the optical waveguides to obtain radio-frequency signals transmitted from the optical waveguides.

The beneficial effects are as follows: according to the present invention, the feed gap is formed on a central axis of two arms of the antenna, and the photodetector is disposed in the feed gap, such that the antenna and the photodetector can be integrated on a same device of a same chip, thereby improving the integration level of an optical integrated circuit and system.

Optionally, the photodetector has the same operating frequency as the antenna. The beneficial effects are as follows: the photodetector has the same operating frequency as the antenna, which contributes to better cooperation between the photodetector and the antenna, thereby improving the operating efficiency of the waveguide photodetector integrated with an antenna.

Optionally, the antenna includes: at least one of a Vivaldi antenna, a bow-tie antenna, a slot antenna, and a patch antenna. The beneficial effects are as follows: the antenna has various designs, such that a type of the said antenna can be changed to meet actual production requirements, such as a requirement for a radiation area of the antenna.

Further optionally, the substrate includes: at least one of silicon, silicon on insulator, silicon on sapphire, silicon dioxide, indium phosphide, lithium niobate, and a polymer. The beneficial effects are as follows: the waveguide photodetector integrated with an antenna can be integrated on the substrate made of any one or more of the above materials to meet actual production requirements.

Further optionally, an operating frequency of the antenna includes an L-band frequency range, an S-band frequency range, a C-band frequency range, an X-band frequency range, a Ku-band frequency range, a K-band frequency range, a KA-band frequency range, and a terahertz frequency range. The beneficial effects are as follows: the operating frequency of the antenna has various frequency types, such that the waveguide photodetector integrated with an antenna can process signals of different frequency ranges.

Further optionally, the optical waveguides include: at least one of channel waveguides, ridge waveguides, slot waveguides, diffused waveguides, and photonic crystal waveguides. The beneficial effects are as follows: the optical waveguides are of different types, and the waveguides of different types have different cross-sectional areas, such that optical waveguides of a proper type are selected according to actual production requirements.

Optionally, said photodetector includes: at least one of a metal photodetector, a semiconductor photodetector, a metal-semiconductor photodetector, and an avalanche photodetector.

Optionally, a wavelength range of the optical signals includes: at least one of a visible band, an O-band, an E-band, an S-band, a C-band, an L-band, a U-band, and a mid-infrared band.

In a second aspect, the present invention provides the system integrating waveguide photodetectors integrated with antennas, including: K arrayed waveguide photodetectors integrated with antennas as described in any one embodiment of the first aspect, where K is a positive integer greater than or equal to 2.

The beneficial effects are as follows: the system integrating waveguide photodetectors can be applied to applications such as phased array radars with real-time delay lines for searching, tracking, and measuring targets.

In a third aspect, the present invention provides a method for sending signals, including: a method applied to the waveguide photodetector integrated with an antenna as described in any one embodiment of the first aspect; obtaining, by the optical waveguides, optical signals modulated at radio frequency, and transmitting the modulated optical signals to the photodetector; receiving, by the photodetector, the modulated optical signals from the optical waveguides, converting the modulated optical signals into electrical radio-frequency signals, and transmitting the electrical radio-frequency signals to the antenna; and obtaining, by the antenna, the electrical radio-frequency signals from the photodetector, and sending out the electrical radio-frequency signals.

The beneficial effects are as follows: the present invention is applied to the waveguide photodetector integrated with an antenna as described in any one embodiment of the first aspect and can improve the integration level of an optical integrated circuit while ensuring the signal sending efficiency, so as to meet actual production requirements.

Optionally, the method for sending signals further includes: obtaining a frequency range of the electrical radio-frequency signals, and modifying or adjusting a design of at least one of the antenna and the photodetector when the frequency range of the electrical radio-frequency signals does not meet a preset requirement, so as to make the frequency range of the electrical radio-frequency signals meet the preset requirement. The beneficial effects are as follows: the design of the antenna and the photodetector is modified or adjusted to make the frequency range of the electrical radio-frequency signals meet the actual requirement.

Optionally, the method for sending signals further includes: adjusting the design of the antenna according to a radiation pattern, so that a radiation direction of the electrical radio-frequency signals meets the preset requirement.

### BRIEF DESCRIPTION OF DRAWINGS

FIG. 1 shows a schematic diagram of an embodiment of a waveguide photodetector integrated with an antenna provided by the present invention;

FIG. 2 shows a schematic diagram of an embodiment of another waveguide photodetector integrated with an antenna provided by the present invention;

FIG. 3 shows a schematic diagram of an embodiment of a system integrating waveguide photodetectors integrated with antennas provided by the present invention;

FIG. 4 shows a flowchart of a method for sending signals provided by the present invention;

FIG. 5 shows a schematic diagram of an embodiment of a simulation result for a radiation pattern of a Vivaldi antenna provided by the present invention; and

FIG. 6 shows a schematic diagram of an embodiment of a simulation result for the performance of a photodetector provided by the present invention.

### DETAILED DESCRIPTION OF EMBODIMENTS

The technical solutions in the embodiments of the present application will be described below with reference to the accompanying drawings in the embodiments of the present application. In the description of the embodiments of the present application herein, the terms in the embodiments below are used only for the purpose of describing specific embodiments but are not intended to be a limitation of the present application. As used in the specification and appended claims of the present application, the singular expressions of “a”, “an”, “the”, “above”, “said”, and “this” are intended to also include the expressions of “one or more”, unless the context clearly indicates otherwise. It should also be understood that, in the following embodiments of the present application, “at least one” and “one or more” refer to one or more than two (including two). The term “and/or” is used to describe a relationship between associated objects and indicates that three types of relationships may exist; for example, “A and/or B” may indicate: the case in which A alone exists, the case in which both A and B exist, and the case in which B alone exists, where A and B may be expressed in the singular or in the plural. The character “/” generally indicates that the contextual associated objects are an “or” relationship.

The reference to “one embodiment” or “some embodiments” described in this specification means that specific features, structures, or characteristics described in conjunction with the embodiment(s) are included in one or more embodiments of the present application. Thus, the statements “in one embodiment”, “in some embodiments”, “in other embodiments”, “in yet other embodiments” and the like, which appear in different parts of this specification, do not necessarily refer to the same embodiment, but mean “one or more embodiments, but not all embodiments”, unless otherwise specifically emphasized in other ways. The terms “include/comprise”, “contain/involve”, “have”, and their variations all mean “including but not limited to”, unless otherwise specifically emphasized in other ways. The term “connection” includes a direct connection and an indirect connection, unless otherwise specified. The terms “first” and “second” are used for descriptive purposes only, and shall not be construed to indicate or imply relative importance or imply the number of technical features indicated.

In the embodiments of the present application, the terms such as “exemplarily” or “for example” are used to indicate examples, illustrations, or explanations. Any embodiment or design solution described as “exemplarily” or “for example” in the embodiments of the present application should not be interpreted as being more preferred or advantageous than other embodiments or design solutions. Rather, the use of the terms such as “exemplarily” or “for example” is intended to present related concepts in a specific manner.

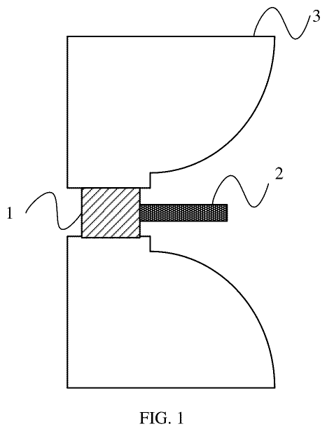

To improve the integration level of an optical integrated circuit, the present invention provides a waveguide photodetector integrated with an antenna. As shown in FIG. 1, the waveguide photodetector integrated with an antenna includes: a photodetector 1, N optical waveguides (as shown in the optical waveguides 2 in FIG. 1) and an antenna 3, where N is a positive integer; the antenna 3 is disposed on a substrate, and a feed gap is formed on a central axis of two arms of the antennal 3, the photodetector 1 being disposed in the feed gap; and the N optical waveguides (as shown in the optical waveguides 2 in FIG. 1) are formed on the substrate, and the photodetector 1 is connected to the optical waveguides 2 to obtain radio-frequency signals over fiber transmitted from the optical waveguides 2.

In this embodiment, the optical waveguides 2 are presented only as an example to explain a structure of the waveguide photodetector integrated with an antenna, and FIG. 1 is not used to limit the number of optical waveguides to which the photodetector can be connected, and the N is set according to actual requirements and may be one or more. According to the present invention, the feed gap is formed on a central axis of two arms of the antenna 3 and the photodetector 1 is disposed in the feed gap, such that the antenna 3 and the photodetector 1 can be integrated on a same chip, thereby improving the integration level of the optical integrated circuit.

In a possible embodiment, the photodetector has a same operating frequency as that of the antenna. In this embodiment, the photodetector has the same operating frequency as the antenna, which contributes to better cooperation between the photodetector and the antenna, thereby improving the operating efficiency of the waveguide photodetector integrated with an antenna.

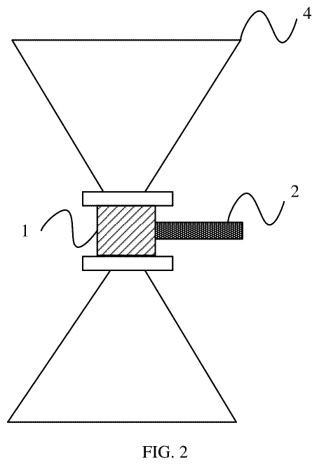

In another possible embodiment, the antenna includes: at least one of a Vivaldi antenna, a bow-tie antenna, a slot antenna, and a patch antenna. In this embodiment, the antenna has various designs, such that a type of the said antenna can be changed to meet actual production requirements, such as a requirement for a radiation area of the antenna. For example, an antenna shown in FIG. 1 is a Vivaldi antenna, and an antenna shown in FIG. 2 is a bow-tie antenna. Namely, a waveguide photodetector integrated with an antenna shown in FIG. 2 includes a photodetector 1, optical waveguides 2, and an antenna 4, wherein the antenna 4 is a bow-tie antenna. In this embodiment, the type of the antenna in the waveguide photodetector integrated with an antenna can be modified to meet different application requirements.

In yet another possible embodiment, the substrate includes: at least one of silicon, silicon on insulator, silicon on sapphire, silicon dioxide, indium phosphide, lithium niobate, and a polymer. In this embodiment, the waveguide photodetector integrated with an antenna can be integrated on the substrate made of any one or more of the above materials to meet actual production requirements.

In a possible embodiment, an operating frequency of the antenna includes an L-band frequency range, an S-band frequency range, a C-band frequency range, an X-band frequency range, a Ku-band frequency range, a K-band frequency range, a KA-band frequency range, and a terahertz frequency range. The X-band refers to the radio wave band with a frequency of 8-12 GHz, which belongs to the microwave band in the electromagnetic spectrum. In some cases, a frequency range of the X-band may be 7-11.2 GHz. The frequency range of a Ku-band is 12-18 GHz. The antenna for receiving Ku-band radio waves has a smaller aperture, thereby effectively reducing the signal-receiving cost. The terahertz range refers to electromagnetic waves with frequencies ranging from 0.1 THz to 10 THz. Terahertz refers to frequencies between a high-frequency edge (300 GHz) of a millimeter-wave band of electromagnetic radiation and a low-frequency far-infrared spectral band edge (3,000 GHz), with a corresponding wavelength of radiation ranging from 0.03 mm to 3 mm (or 30-3,000 μm) in the frequency band range. A photon energy at a frequency of 1 THz is only about 4 millielectronvolts, such that a detected material is not easily damaged. In this embodiment, the operating frequency of the antenna has various frequency types, such that the waveguide photodetector integrated with an antenna can process signals of different frequency ranges.

In yet another possible embodiment, the optical waveguides include: at least one of channel waveguides, ridge waveguides, slot waveguides, diffused waveguides, and photonic crystal waveguides. Common optical waveguides are channel waveguides and ridge waveguides. In this embodiment, the optical waveguides are of different types, and the waveguides of different types have different cross-sectional areas, such that optical waveguides of a proper type are selected according to actual production requirements.

In still another possible embodiment, the photodetector includes: at least one of a metal photodetector, a semiconductor photodetector, a metal-semiconductor photodetector, and an avalanche photodetector. Photodetectors of different types are applicable to different applications.

In a possible embodiment, a wavelength range of the optical signals includes: at least one of a visible band, an O-band, an E-band, an S-band, a C-band, an L-band, a U-band, and a mid-infrared band.

Based on the waveguide photodetector integrated with an antenna described in any one of the above embodiments, the present invention provides the system integrating waveguide photodetectors integrated with antennas, including: K arrayed waveguide photodetectors integrated with antennas as described in any one of the above embodiments, where K is a positive integer greater than or equal to 2.

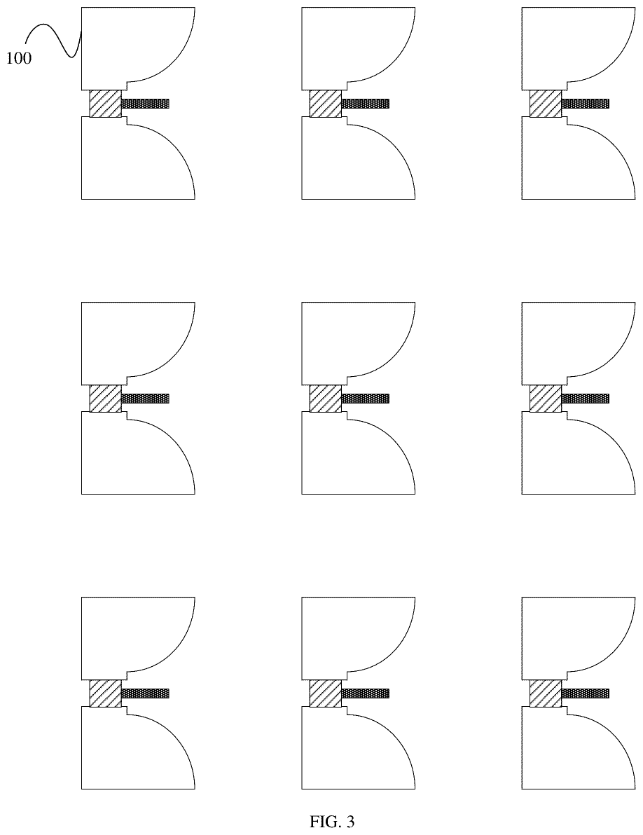

As shown in FIG. 3, the system integrating waveguide photodetectors integrated with antennas includes: nine waveguide photodetectors 100 integrated with antennas arranged in a 3×3 matrix. Since K is a positive integer greater than or equal to 2, the system integrating waveguide photodetectors integrated with antennas includes at least two of said waveguide photodetectors integrated with antennas, and an array composed of the said waveguide photodetectors integrated with antennas may be irregularly shaped. The system integrating waveguide photodetectors integrated with antennas can be applied to applications such as phased array radars for searching, tracking, and measuring targets. The waveguide photodetector integrated with an antenna can improve the integration level of an optical integrated device, such that the system integrating waveguide photodetectors integrated with antennas which includes the waveguide photodetectors integrated with antennas also improves the integration level of the optical integrated device and system.

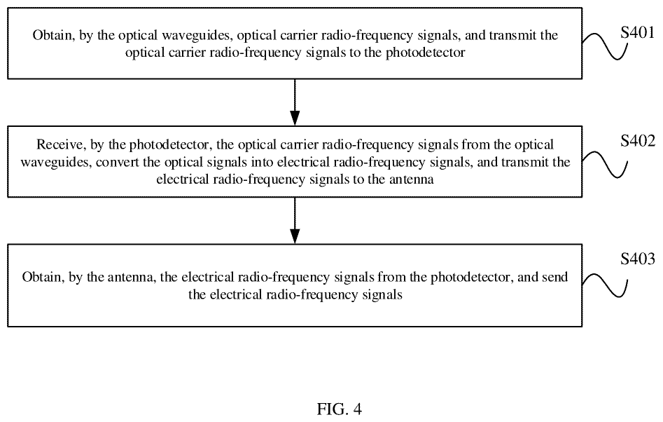

In addition, the present invention provides a method for sending signals based on the waveguide photodetector integrated with an antenna provided in any one of the above embodiments, with a flowchart as shown in FIG. 4. The method includes the following specific steps:
S401: obtaining optical carrier radio-frequency signals by the optical waveguides, and transmitting the optical carrier radio-frequency signals to the photodetector;
S402: receiving the optical carrier radio-frequency signals from the optical waveguides by the photodetector, converting the optical carrier radio-frequency signals into electrical radio-frequency signals and transmitting the electrical radio-frequency signals to the antenna; and
S403: obtaining the electrical radio-frequency signals from the photodetector by the antenna, and sending the electrical radio-frequency signals.

The method for sending signals provided by the present invention is applied to the waveguide photodetector integrated with an antenna as described in any one of the above embodiments and can improve the integration level of an optical integrated circuit while ensuring the signal sending efficiency, so as to meet actual production requirements.

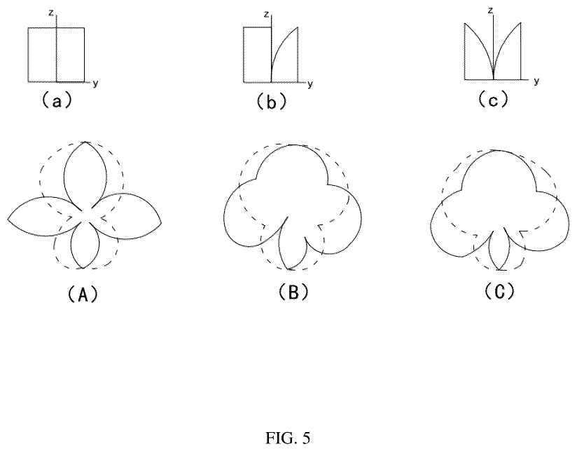

In a possible embodiment, the method for sending signals further includes: obtaining a frequency range of the electrical radio-frequency signals, and when the frequency range of the electrical radio-frequency signals does not meet a preset requirement, modifying or adjusting a design of at least one of the antenna and the photodetector, so as to make the frequency range of the electrical radio-frequency signals meet the preset requirement. In this embodiment, at least one of a size of the antenna, an RC setting of the photodetector, and a carrier transit time of the photodetector is modified to make the frequency range of the electrical radio-frequency signals meet the actual requirement. In a possible embodiment, the method for sending signals further includes: adjusting the design of the antenna in accordance with a radiation pattern. Exemplarily, an antenna used is a Vivaldi antenna, and the profiles of the antenna are as shown in FIG. 5(a), (b) and (c), respectively, where FIG. 5(b) shows that a feed gap is left between a first arm and a second arm of the antenna, and a photodetector is disposed in the feed gap; radiation patterns of the waveguide photodetector integrated with an antenna are as shown in FIG. 5(A), (B) and (C), respectively, wherein “y” in FIG. 5 represents a y-axis in a coordinate axis, “z” in FIG. 5 represents a z-axis in the coordinate axis, and a direction of an x-axis (not shown in the figure) is perpendicular to a plane of the y-axis and the z-axis. In FIG. 5(A), (B) and (C), a solid outline represents a radiation pattern of a waveguide photodetector integrated with an antenna corresponding to a y-z plane, and a dashed outline represents a radiation pattern of a waveguide photodetector integrated with an antenna corresponding to an x-y plane.

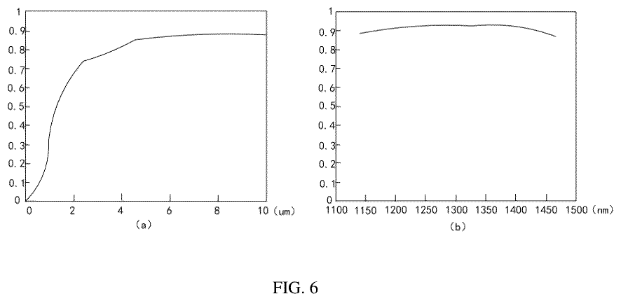

The specific structure of the photodetector mentioned in the present application and the absorbing material on the photodetector are not limited. For example, the absorbing material includes germanium, silicon, a III-V material, and a metal. A specific position of a contact, used to connect said antenna, on the photodetector is not limited. When the absorbing material on the photodetector is germanium, a simulation result for the performance of the photodetector is as shown in FIG. 6. A horizontal axis in FIG. 6(a) represents a light propagation distance in micrometers (um), a vertical axis in FIG. 6(a) represents a normalized total absorption efficiency, and FIG. 6(a) shows a change in the normalized total absorption efficiency along with a change in the light propagation distance within an absorption region; and a horizontal axis in FIG. 6(b) represents a wavelength in nanometers (nm), a vertical axis in FIG. 6(b) represents an optical responsivity, and FIG. 6(b) shows a change of the optical responsivity along with a change of the wavelength near an O-band.

The foregoing are only specific implementations of the embodiments of the present application, but the scope of protection of the embodiments of the present application is not limited thereto. Any changes or substitutions within the technical scope disclosed in the embodiments of the present application should all be included in the scope of protection of the embodiments of the present application. Therefore, the scope of protection of the embodiments of the present application should be subject to the scope of protection of the claims.

1. A waveguide photodetector integrated with an antenna, wherein the photodetector comprises: a photodetector, N optical waveguides and an antenna, where N is a positive integer;
the antenna is disposed on a substrate, and a feed gap is formed on a central axis of two arms of the antenna, the photodetector being disposed in the feed gap; and
the N optical waveguides are formed on the substrate, and the photodetector is connected to the optical waveguides to obtain radio-frequency signals transmitted from the optical waveguides.

2. The waveguide photodetector according to claim 1, wherein the photodetector has a same operating frequency as that of the antenna.

3. The waveguide photodetector according to claim 1, wherein the antenna comprises at least one of a Vivaldi antenna, a bow-tie antenna, a slot antenna, and a patch antenna.

4. The waveguide photodetector according to claim 1, wherein the substrate comprises at least one of silicon, silicon on insulator, silicon on sapphire, silicon dioxide, indium phosphide, lithium niobate and a polymer.

5. The waveguide photodetector according to claim 1, wherein an operating frequency range of the antenna comprises an L-band frequency range, an S-band frequency range, a C-band frequency range, an X-band frequency range, a Ku-band frequency range, a K-band frequency range, a KA-band frequency range, and a terahertz frequency range.

6. The waveguide photodetector according to claim 1, wherein the optical waveguides comprise at least one of channel waveguides, ridge waveguides, slot waveguides, diffused waveguides and photonic crystal waveguides.

7. The waveguide photodetector according to claim 1, wherein the photodetector comprises: at least one of a metal photodetector, a semiconductor photodetector, a metal-semiconductor photodetector and an avalanche photodetector.

8. The waveguide photodetector according to claim 1, wherein a wavelength range of the optical signals comprises at least one of a visible band, an O-band, an E-band, an S-band, a C-band, an L-band, a U-band, and a mid-infrared band.

9. A system integrating waveguide photodetectors integrated with antennas, wherein the system comprises K arrayed waveguide photodetectors integrated with antennas according to claim 1, where K is a positive integer greater than or equal to 2.

10. A method for sending signals, wherein it comprises a method applied to the waveguide photodetector integrated with an antenna according to claim 1, wherein the method comprises:
obtaining optical carrier radio-frequency signals by the optical waveguides, and transmitting the optical carrier radio-frequency signals to the photodetector;
receiving the optical carrier radio-frequency signals from the optical waveguides by the photodetector, converting the optical carrier radio-frequency signals into electrical radio-frequency signals and transmitting the electrical radio-frequency signals to the antenna; and
obtaining the electrical radio-frequency signals from the photodetector by the antenna, and sending the electrical radio-frequency signals.

11. The method for sending signals according to claim 10, wherein it further comprises:
obtaining a frequency range of the electrical radio-frequency signals, and modifying or adjusting a design of at least one of the antenna and the photodetector when the frequency range of the electrical radio-frequency signals does not meet a preset requirement, so as to make the frequency range of the electrical radio-frequency signals meet the preset requirement.

12. The method for sending signals according to claim 11, wherein it further comprises:
adjusting the design of the antenna according to a radiation pattern, so that a radiation direction of the electrical radio-frequency signals meets the preset requirement.
